(19) United States
(12) Patent Application Publication
(10) Pub. No.: US 2026/0129922 A1
(43) Pub. Date: May 7, 2026

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Tomofumi NIIBAYASHI, Nisshin-shi (JP); Jun Saito, Nisshin-shi (JP)

(21) Appl. No.: 19/351,409

(22) Filed: Oct. 7, 2025

(30) Foreign Application Priority Data
Nov. 6, 2024 (JP) 2024-194228

(51) Int. Cl. H10D 62/10; H10D 30/66; H10D 62/00; H10D 62/832

(52) U.S. Cl. CPC H10D 62/111; H10D 30/668; H10D 62/054; H10D 62/8325

(57) ABSTRACT

A semiconductor device includes a voltage sustaining layer of a first conductivity type and a superjunction layer disposed in contact with an upper surface of the voltage sustaining layer. The superjunction layer includes first regions of the first conductivity type and second regions of a second conductivity type alternately arranged along a first direction. Each of the second regions includes a lower second region in contact with the voltage sustaining layer and an upper second region disposed in contact with an upper surface of the lower second region. A lower maximum width that is a maximum width in the first direction of the lower second region is greater than an upper maximum width that is a maximum width in the first direction of the upper second region. A density of fixed charges during depletion is higher in the lower second region than in the upper second region.

### CROSS REFERENCE TO RELATED APPLICATION

The present application claims the benefit of priority from Japanese Patent Application No. 2024-194228 filed on Nov. 6, 2024. The entire disclosure of the above application is incorporated herein by reference.

### TECHNICAL FIELD

The present disclosure relates to a semiconductor device.

### BACKGROUND

Semiconductor devices are known that have a structure in which a superjunction (SJ) layer is disposed on an upper surface of a voltage sustaining layer (also referred to as a drift layer) that shares the breakdown voltage. In such semiconductor devices, since the SJ layer is substantially fully depleted, a depletion layer is formed over a wide area, making it possible to ensure sufficient breakdown voltage.

### SUMMARY

A semiconductor device according to an aspect of the present disclosure includes a voltage sustaining layer of a first conductivity type and a superjunction layer disposed in contact with an upper surface of the voltage sustaining layer. The superjunction layer includes first regions of the first conductivity type and second regions of a second conductivity type alternately arranged along a first direction. Each of the second regions includes a lower second region in contact with the voltage sustaining layer and an upper second region disposed in contact with an upper surface of the lower second region. The lower second region has a lower maximum width that is a maximum width in the first direction of the lower second region. The upper second region has an upper maximum width that is a maximum width in the first direction of the upper second region. The lower maximum width may be greater than the upper maximum width. A density of fixed charges during depletion may be higher in the lower second region than in the upper second region.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of a part of a semiconductor device according to a first embodiment;

FIG. 2 is an enlarged view of a part of the vicinity of an SJ layer in the semiconductor device according to the first embodiment;

FIG. 3 is an enlarged view of a part of the vicinity of an SJ layer in a semiconductor device of a comparative example;

FIG. 4 is an enlarged view of a part of the vicinity of the SJ layer in the semiconductor device according to the first embodiment;

FIG. 5 is a diagram illustrating a process for forming the SJ layer;

FIG. 6 is a diagram illustrating a process for forming the SJ layer;

FIG. 7 is a diagram illustrating a process for forming the SJ layer;

FIG. 8 is an enlarged view of a part of the vicinity of the SJ layer in a semiconductor device according to a second embodiment;

FIG. 9 is a diagram illustrating an effect in the second embodiment;

FIG. 10 is a diagram illustrating a process for forming the SJ layer;

FIG. 11 is an enlarged view of a part of the vicinity of an SJ layer in a semiconductor device according to a third embodiment; and

FIG. 12 is a diagram showing examples of various cross-sectional shapes of lower second regions.

### DETAILED DESCRIPTION

In semiconductor devices having a structure in which a superjunction layer is disposed on a drift layer, there are cases where a depletion layer is difficult to extend from the superjunction layer into the interior of the drift layer. In such cases, since an electric field inside the drift layer is low, there is a possibility that a breakdown voltage of the drift layer cannot be sufficiently ensured.

A semiconductor device according to a first aspect of the present disclosure includes a voltage sustaining layer of a first conductivity type and a superjunction layer disposed in contact with an upper surface of the voltage sustaining layer. The superjunction layer includes first regions of the first conductivity type and second regions of a second conductivity type alternately arranged along a first direction. Each of the second regions includes a lower second region in contact with the voltage sustaining layer and an upper second region disposed in contact with an upper surface of the lower second region. The lower second region has a lower maximum width that is a maximum width in the first direction of the lower second region. The upper second region has an upper maximum width that is a maximum width in the first direction of the upper second region. The lower maximum width is greater than the upper maximum width. A density of fixed charges during depletion is higher in the lower second region than in the upper second region.

According to the configuration of the first aspect, the density of fixed charges during depletion is higher in the lower second region than in the upper second region. Therefore, to the extent that the density of fixed charges in the lower second region is higher, the progression of the depletion layer into the voltage sustaining layer in contact with the lower second region can be promoted. Since the electric field shared by the voltage sustaining layer can be increased, the breakdown voltage of the voltage sustaining layer can be improved.

According to a second aspect of the present disclosure, the semiconductor device according to the first aspect has a configuration in which the lower second region has a higher concentration of a second conductivity type impurity than the upper second region.

According to the configuration of the second aspect, to the extent that the concentration of the second conductivity type impurity in the lower second region is higher, the progression of the depletion layer into the voltage sustaining layer in contact with the lower second region can be promoted. It becomes possible to improve the breakdown voltage of the drift layer.

According to a third aspect of the present disclosure, the semiconductor device according to the first aspect or the second aspect has a configuration in which a width in the first direction of the lower second region at an interface between the lower second region and the voltage sustaining layer is the lower maximum width.

According to the configuration of the third aspect, at a pn junction interface between the lower second region and the voltage sustaining layer, the density of fixed charges during depletion can be made higher in the lower second region than in the upper second region.

According to a fourth aspect of the present disclosure, the semiconductor device according to any one of the first to third aspects has a configuration in which each of the first regions includes a lower first region in contact with the voltage sustaining layer and an upper first region disposed in contact with an upper surface of the lower first region, the lower first region is disposed between the lower second regions that are adjacent to each other in the first direction, the upper first region is disposed between the upper second regions that are adjacent to each other in the first direction, and the density of fixed charges during depletion is lower in the lower first region than in the upper first region.

According to the configuration of the fourth aspect, to the extent that the amount of fixed charges in the lower first region can be reduced, the effect of expanding the depletion layer in the voltage sustaining layer by the amount of fixed charges in the lower second region can be enhanced.

According to a fifth aspect of the present disclosure, the semiconductor device according to the fourth aspect has a configuration in which, when viewed vertically from above the superjunction layer, the voltage sustaining layer has overlapping regions that overlap with the lower first regions and the lower second regions, a total amount of fixed charges in the overlapping regions during depletion is defined as an overlapping region total charge, a total amount of fixed charges in the lower first regions during depletion is defined as a first region total charge, a total amount of fixed charges in the lower second regions during depletion is defined as a second region total charge, and the second region total charge is equal to or greater than a sum of the first region total charge and the overlapping region total charge.

According to the configuration of the fifth aspect, the amount of fixed charges in the lower second regions can be set to a quantity sufficient to recombine with the amount of fixed charges in the lower first regions and the overlap regions. This allows the depletion layer to extend over the entire area of the voltage sustaining layer. By fully depleting the voltage sustaining layer, it becomes possible to maximize the breakdown voltage of the voltage sustaining layer.

According to a sixth aspect of the present disclosure, the semiconductor device according to any one of the first to fifth aspects has a configuration in which the first conductivity type is n-type and the second conductivity type is p-type.

A semiconductor device according to a seventh aspect of the present disclosure includes a voltage sustaining layer of a first conductivity type and a superjunction layer disposed in contact with an upper surface of the voltage sustaining layer. The superjunction layer includes first regions of the first conductivity type and second regions of a second conductivity type alternately arranged along a first direction. Each of the second regions includes a lower second region in contact with the voltage sustaining layer and an upper second region disposed in contact with an upper surface of the lower second region. The lower second region has a lower maximum width that is a maximum width in the first direction of the lower second region. The upper second region has an upper maximum width that is a maximum width in the first direction of the upper second region. The lower maximum width is greater than the upper maximum width. The lower second region has a higher concentration of a second conductivity type impurity than the upper second region.

### First Embodiment

Hereinafter, semiconductor devices according to embodiments of the present disclosure will be described. For the purpose of clarity of drawings, when components are repeatedly arranged, only one of the components may be denoted by a reference numeral.

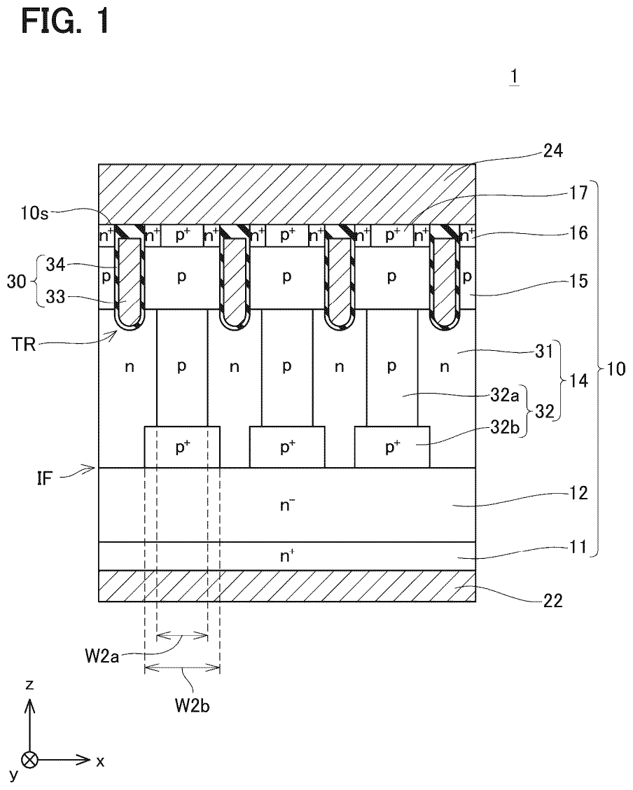

As shown in FIG. 1, a semiconductor device 1 according to a first embodiment is a type of power semiconductor device called a metal-oxide-semiconductor field effect transistor (MOSFET). The semiconductor device 1 includes a semiconductor substrate 10, a drain electrode 22 covering a lower surface of the semiconductor substrate 10, a source electrode 24 covering an upper surface of the semiconductor substrate 10, and a plurality of trench gates 30 provided in an upper layer portion of the semiconductor substrate 10.

The material of the semiconductor substrate 10 is not particularly limited. In the present embodiment, silicon carbide is used. Furthermore, nitrogen is used as an n-type impurity, and aluminum is used as a p-type impurity. The semiconductor substrate 10 includes a drain region 11 of n⁺-type, a drift region 12 of n⁻type, a superjunction (SJ) layer 14, a body region 15, a source region 16, and a body contact region 17.

The drain region 11 is disposed at a position exposed on the lower surface of the semiconductor substrate 10. The drain region 11 contains the n-type impurity at a high concentration and is in ohmic contact with the drain electrode 22. The drift region 12 is disposed between the drain region 11 and the SJ layer 14, and is in contact with both the drain region 11 and the SJ layer 14. The concentration of the n-type impurity in the drift region 12 is lower than that in the drain region 11.

The SJ layer 14 is disposed on an upper surface of the drift region 12. The SJ layer 14 includes a plurality of first regions 31 of n-type conductivity and a plurality of second regions 32 of p-type conductivity. The first regions 31 and the second regions 32 are alternately arranged along the x-direction. Although the arrangement is not particularly limited, the plurality of first regions 31 and the plurality of second regions 32 may, for example, be arranged in a stripe pattern when viewed from a direction (+z direction) perpendicular to the upper surface 10s of the semiconductor substrate 10.

Each of the plurality of second regions 32 includes a lower second region 32b and an upper second region 32a. The lower second region 32b is a region having a higher concentration of p-type impurity than the upper second region 32a. The lower second region 32b is in contact with the drift region 12. The upper second region 32a is disposed in contact with an upper surface of the lower second region 32b.

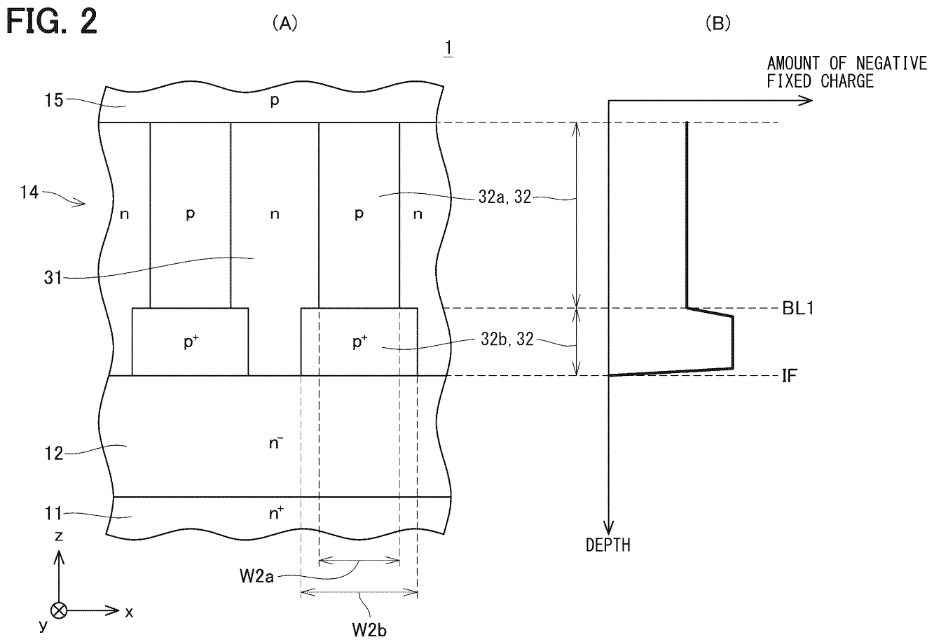

The lower second region 32b and the upper second region 32a will be described with reference to FIG. 2. In FIG. 2, (A) is an enlarged view of a part of the vicinity of the SJ layer 14. It should be noted that in (A) of FIG. 2, the trench gates 30 are omitted. In FIG. 2, (B) is a diagram showing the depth distribution of the amount of negative fixed charges when the second region 32 is depleted. The distribution of the amount of negative fixed charges can be obtained, for example, by subtracting the donor impurity concentration distribution from the acceptor impurity concentration distribution.

The concentration of the p-type impurity contained in the lower second region 32b is set higher than the concentration of the p-type impurity contained in the upper second region 32a. Therefore, as shown in (B) of FIG. 2, when the second region 32 is depleted, the density of negative fixed charges is higher in the lower second region 32b than in the upper second region 32a. Furthermore, there is a boundary BL1 between the lower second region 32b and the upper second region 32a at which the amount of negative fixed charges changes abruptly.

The lower second region 32b has a lower maximum width W2b, which is the maximum width in the x-direction. In the present embodiment, the width of the lower second region 32b in the x-direction is constant in the depth direction (z-direction). Therefore, the width of the lower second region 32b is the lower maximum width W2b throughout the entire depth direction. That is, the width of the lower second region 32b at an interface IF between the lower second region 32b and the drift region 12 is the lower maximum width W2b. The upper second region 32a has an upper maximum width W2a, which is the maximum width in the x-direction. In the present embodiment, the width of the upper second region 32a in the x-direction is constant in the depth direction (z-direction). Therefore, the width of the upper second region 32a is the upper maximum width W2a throughout the entire depth direction. The lower maximum width W2b is set to be larger than the upper maximum width W2a.

It should be noted that the upper maximum width W2a, the lower maximum width W2b, and the height in the z-direction of each of the lower second region 32b and the upper second region 32a may have various values. The distribution of the amount of negative fixed charges (see (B) of FIG. 2) is not limited to the mode of the present embodiment and may vary in various ways.

As shown in FIG. 1, the body region 15 is disposed on the SJ layer 14. The body region 15 is disposed between the SJ layer 14 and the source region 16, is in contact with both the SJ layer 14 and the source region 16, and separates the SJ layer 14 from the source region 16. The concentration of the p-type impurity in the body region 15 is adjusted according to the desired gate threshold voltage.

The source region 16 is disposed on the body region 15 and is formed at a position exposed on the upper surface 10s of the semiconductor substrate 10. The source region 16 is in contact with an upper side surface of the trench gate 30. The source region 16 contains the n-type impurity at a high concentration and is in ohmic contact with the source electrode 24.

The body contact region 17 is disposed on the body region 15 in the upper layer of the semiconductor substrate 10, and is formed at a position exposed on the upper surface 10s of the semiconductor substrate 10. The body contact region 17 is in ohmic contact with the source electrode 24, which covers the upper surface 10s.

A plurality of trenches TR penetrate the body region 15 from a surface of the source region 16 and reach the plurality of first regions 31, respectively. The plurality of trench gates 30 are disposed inside the plurality of trenches TR, respectively. Each of the plurality of trench gates 30 includes a gate electrode 33 and a gate insulating layer 34. The gate insulating layer 34 is formed of silicon oxide and covers an inner wall of each of the plurality of trenches TR. The gate electrode 33 is formed of polysilicon containing impurities. Each of the plurality of trench gates 30 extends in the y-direction when viewed in cross-section of the semiconductor substrate 10. Furthermore, the plurality of trench gates 30 are arranged at intervals from each other along a direction (x-direction) perpendicular to their longitudinal direction. That is, when the semiconductor substrate 10 is viewed in plan (viewed from the z-direction), the plurality of trench gates 30 are located within the plurality of first regions 31, respectively.

### [Operation of the Semiconductor Device 1]

When the potential of the gate electrode 33 of each of the plurality of trench gates 30 is positive relative to the source electrode 24 and controlled to be higher than a threshold value, while the potential of the drain electrode 22 is positive relative to the potential of the source electrode 24, the semiconductor device 1 is turned on. At this time, inversion layers are formed at portions of the body region 15 that separate the source region 16 and the plurality of first regions 31 of the SJ layer 14. Electrons supplied from the source region 16 reach the plurality of first regions 31 of the SJ layer 14 via channels of the inversion layers. The electrons that reach the plurality of first regions 31 flow through the plurality of first regions 31, and then through the drift region 12 and the drain region 11. Since the plurality of first regions 31 have a high concentration of the n-type impurity, the semiconductor device 1 can have low on-resistance.

When the potential of the gate electrode 33 of each of the plurality of trench gates 30 is controlled to be the same as the potential of the source electrode 24, the channels of the inversion layers disappear, and the semiconductor device 1 is turned off. In the SJ layer 14, in the repetition direction (x-direction), the density of positive fixed charges when the plurality of first regions 31 are depleted and the density of negative fixed charges when the plurality of second regions 32 are depleted are balanced with each other. Accordingly, the plurality of first regions 31 and the plurality of second regions 32 are substantially fully depleted, and a wide area of the SJ layer 14 is depleted. In addition, the electric field distribution in the SJ layer 14 is leveled in the depth direction. Therefore, the SJ layer 14 can withstand a large potential difference, and the semiconductor device 1 can have high breakdown voltage.

### [Issues and Effects]

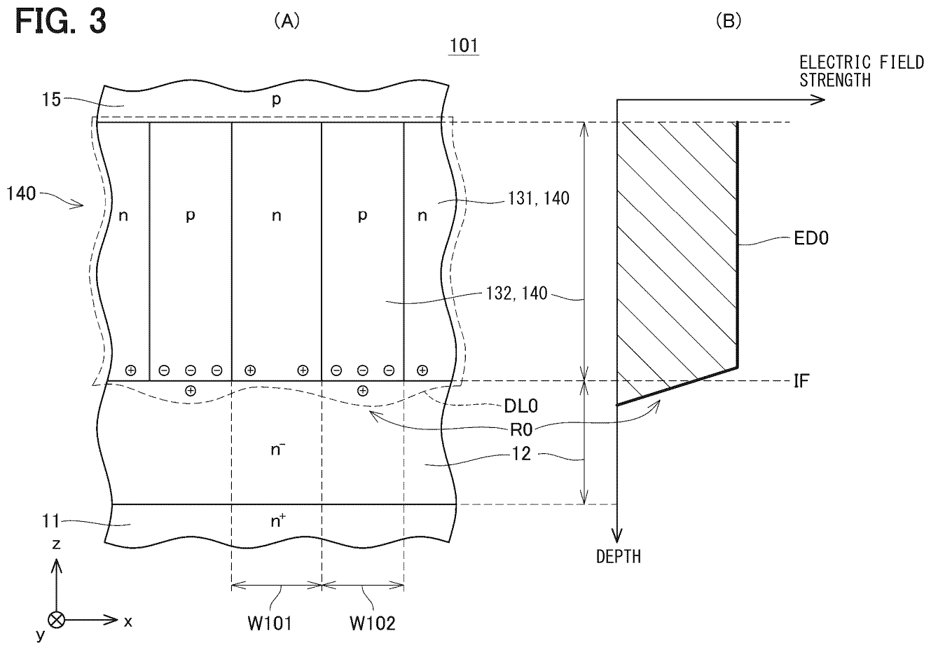

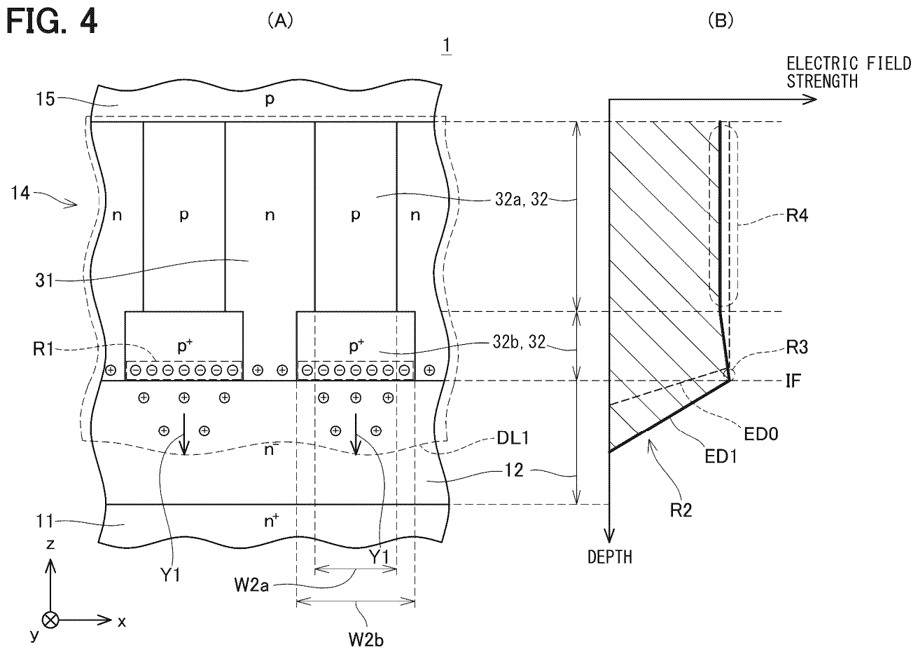

FIG. 3 shows a semiconductor device 101 of a comparative example. FIG. 4 shows the semiconductor device 1 of the present embodiment. In each of FIG. 3 and FIG. 4, (A) shows a partially enlarged view of the vicinity of the SJ layer. In (A) of each of FIGS. 3 and 4, the trench gates 30 are omitted, and the depletion layer during depletion is indicated by a dotted-line region. In addition, among the fixed charges present at an interface IF between the SJ layer 14 and the drift region 12, positive fixed charges are schematically indicated by circles with a plus sign (+), and negative fixed charges are schematically indicated by circles with a minus sign (−). In each of FIG. 3 and FIG. 4, (B) shows an electric field distribution within the second region when the second region is depleted.

The issues will be explained using the comparative example shown in FIG. 3. In the comparative example, the structure of the second regions 132 in the SJ layer 140 shown in (A) of FIG. 3 differs from the structure of the second regions 14 in the SJ layer 14 of the present embodiment shown in (A) of FIG. 4. In the second regions 132, the concentration of p-type impurities is uniform throughout the entire depth direction (z-direction). Accordingly, the second regions 132 are not divided into upper regions and lower regions. Furthermore, the second regions 132 have a constant width W102 throughout the entire depth direction. Similarly, the first regions 131 have a constant width W101 throughout the entire depth direction.

When a voltage is applied to the semiconductor device 101, negative fixed charges are generated in the second regions 132 in the vicinity of the interface IF, and positive fixed charges are generated in the first regions 131 and the drift region 12 (see (A) of FIG. 3). In the semiconductor device 101, at any given depth, the amounts of fixed charges in the second regions 132 and the first regions 131 are made to be approximately the same. Accordingly, the SJ layer 140 is substantially fully depleted, and a depletion layer DL0 is formed throughout the entire SJ layer 140. Since the electric field distribution in the SJ layer 140 becomes approximately uniform (see (B) of FIG. 3), it is possible to ensure sufficient breakdown voltage. However, in this case, because the positive and negative fixed charges in the SJ layer 140 are balanced, the depletion layer DL0 is difficult to extend into the interior of the drift region 12. Because the electric field inside the drift region 12 is low, the breakdown voltage of the drift region 12 may not be sufficiently ensured (see region R0 in (A) of FIG. 3). In other words, in the electric field distribution ED0 shown in (B) of FIG. 3, the hatched area indicates the breakdown voltage; however, the area within the drift region 12 is small.

The effects will be explained using the present embodiment shown in FIG. 4. In the semiconductor device 1 of the present embodiment shown in (A) of FIG. 4, as described above, the lower second regions 32b have a higher concentration of p-type impurities than the upper second regions 32a. That is, the negative fixed charges density during depletion is higher in the lower second regions 32b than in the upper second regions 32a. In addition, the lower maximum width W2b of the lower second regions 32b is set to be larger than the upper maximum width W2a of the upper second regions 32a. That is, the amount of negative fixed charges during depletion is greater in the lower second regions 32b than in the upper second regions 32a. As a result of the above effects, the amount of negative fixed charges in the vicinity of the interface IF can be increased compared to the comparative example (see region R1 in (A) of FIG. 4). To the extent that a larger amount of negative fixed charges can be provided in the vicinity of the interface IF of the lower second regions 32b, the extension of a depletion layer DL1 into the drift region 12, which is in contact with the lower second regions 32b, can be promoted (see arrow Y1).

In FIG. 4, (B) shows the electric field distribution ED1 (solid line) in the present embodiment and the electric field distribution ED0 (dotted line) in the comparative example. In the electric field distribution ED1 of the present embodiment, the shared electric field in the drift region 12 can be increased compared to the electric field distribution ED0 of the comparative example. In other words, the area within the drift region 12 can be larger in the electric field distribution ED1 than in the electric field distribution ED0 (see region R2). As a result, in the semiconductor device 1 of the present embodiment, it becomes possible to improve the breakdown voltage of the drift region 12.

It should be noted that, in the present embodiment, the electric field in the vicinity of the interface IF of the lower second regions 32b increases (see region R3). Accordingly, the electric field inside the SJ layer 14 is reduced in the electric field distribution ED1 of the present embodiment compared to the electric field distribution ED0 of the comparative example (see region R4). However, in the present embodiment, since only the lower second regions 32b have a widened structure, it is possible to reduce the influence of the divided electric field on the upper second regions 32a. Accordingly, it is possible to reduce the amount of decrease in the electric field inside the SJ layer 14 (region R4). As a result, while maintaining a high electric field within the SJ layer 14, it is possible to further increase the total area of the electric field distribution ED1 by increasing the shared electric field of the drift region 12. This makes it possible to increase the breakdown voltage of the semiconductor device 1.

### [Manufacturing Method of Semiconductor Device 1]

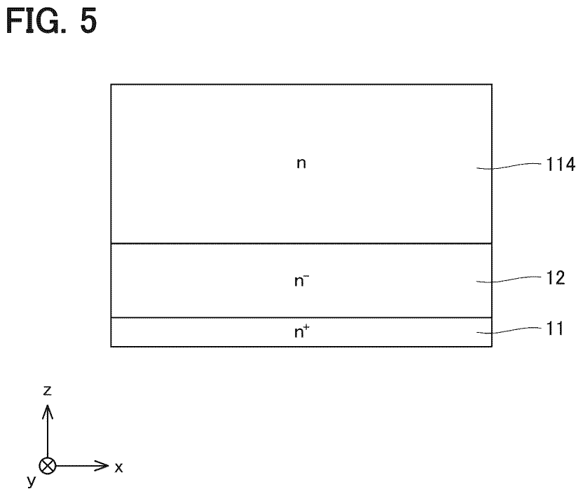

Next, with reference to FIGS. 5 to 7, a process of forming the SJ layer 14 in a manufacturing method of the semiconductor device 1 will be described. Other processes of manufacturing the semiconductor device 1 can utilize known manufacturing techniques.

First, the drain region 11, which is an n⁺-type silicon carbide substrate, is prepared. Next, using epitaxial growth techniques, the drift region 12 of n-type and an epitaxial layer 114, which are made of silicon carbide, are grown from a surface of the drain region 11. As a result, the structure shown in FIG. 5 is completed. The concentration of the n-type impurity is lower in the drift region 12 than in the epitaxial layer 114. In addition, the concentration distribution of the n-type impurity in the depth direction (z-direction) is made uniform in each of the drift region 12 and the epitaxial layer 114. The concentration distribution of the n-type impurity may be adjusted during the epitaxial growth of the drift region 12 and the epitaxial layer 114, may be adjusted using ion implantation techniques after epitaxial growth, or may be adjusted by a combination of these methods.

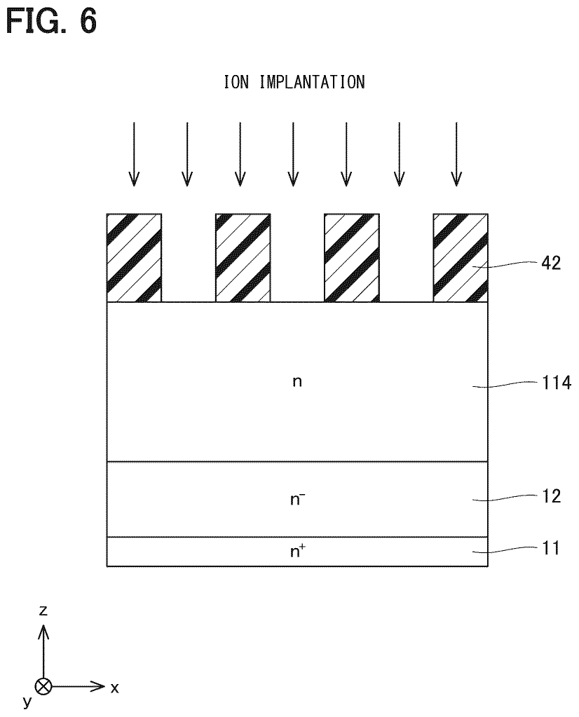

Next, as shown in FIG. 6, a mask 42 is formed on the epitaxial layer 114 using known photolithography techniques. The mask 42 is a stripe-shaped mask having openings at positions corresponding to the upper second regions 32a. The mask 42 may be a resist mask formed of resist, or may be a hard mask formed of a silicon oxide film or the like.

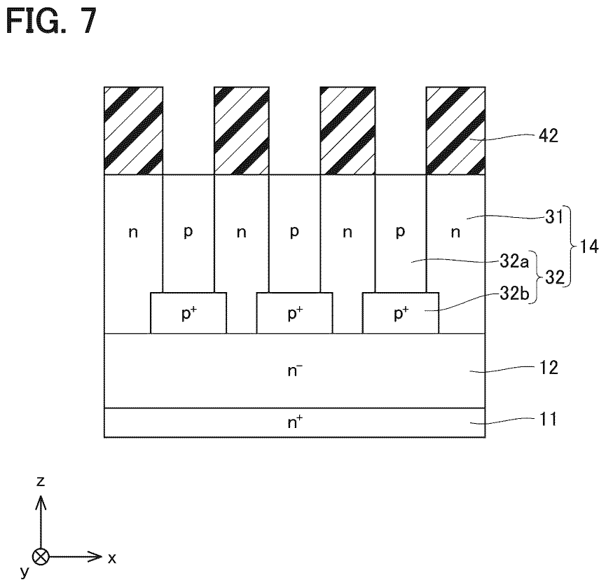

Next, as shown in FIG. 6, an ion implantation process is performed. Specifically, p-type impurity ions are implanted in multiple steps through the mask 42 so as to cover the entire depth of the epitaxial layer 114. At this time, ion implantation is controlled so that the amount implanted into the lower side of the epitaxial layer 114 is greater than the amount implanted into the upper side. As a result, as shown in FIG. 7, it is possible to form the SJ layer 14 having the lower second regions 32b and the upper second regions 32a.

A method for forming the lower second regions 32b so that the width W2b is larger than the width W2a of the upper second regions 32a will be described. The implanted impurity ions have the property of scattering laterally (in the direction perpendicular to the implantation direction) within the semiconductor substrate. This lateral scattering tends to increase as the implantation dose of impurity ions increases. Therefore, by making the implantation dose on the lower side of the epitaxial layer 114 greater than that on the upper side, it is possible to increase the amount of ion scattering on the lower side. Furthermore, lateral scattering tends to increase as the range of the impurity ions becomes longer. Therefore, by implanting ions from the same substrate surface, the amount of ion scattering in the lower second regions 32b can be increased relative to the amount of ion scattering in the upper second regions 32a. As a result, it becomes possible to make the width W2b greater than the width W2a.

In the manufacturing method of the present embodiment, it is possible to form the lower second regions 32b and the upper second regions 32a, which have different widths, using the single mask 42. Compared to the case where multiple masks are used for each region width and ion implantation is performed multiple times, the process can be simplified, thus reducing manufacturing costs.

### Second Embodiment

### [Structure of Semiconductor Device 201]

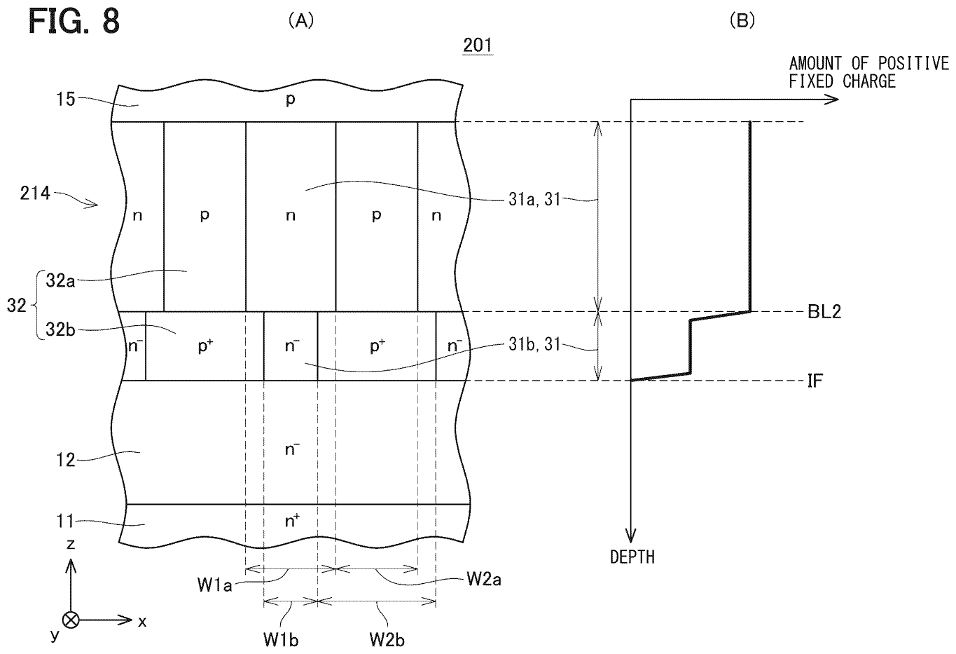

FIG. 8 shows a semiconductor device 201 of a second embodiment. In FIG. 8, (A) and (B) show the same positions as (A) and (B) of FIG. 2 of the first embodiment. The semiconductor device 201 includes an SJ layer 214. The SJ layer 214 of the second embodiment has a different structure for the first regions 31 compared to the SJ layer 14 of the first embodiment. For portions common to both the first and second embodiments, the same reference numerals are used, and the description thereof is omitted.

Each of the first regions 31 of the second embodiment includes a lower first region 31b and an upper first region 31a. The lower first region 31b is a region having a lower n-type impurity concentration than the upper first region 31a. The lower first region 31b is in contact with the drift region 12. The upper first region 31a is disposed in contact with the upper surface of the lower first region 31b. The lower first region 31b is disposed between the lower second regions 32b that are adjacent to each other in the x-direction. The upper first region 31a is disposed between the upper second regions 32a that are adjacent to each other in the x-direction.

The lower first region 31b has a lower maximum width W1b, which is the maximum width in the x-direction. In the present embodiment, the width of the lower first region 31b in the x-direction is constant in the depth direction (z-direction). The upper first region 31a has an upper maximum width W1a, which is the maximum width in the x-direction. In the present embodiment, the width of the upper first region 31a in the x-direction is constant in the depth direction (z-direction). Then, the lower maximum width W1b is set to be smaller than the upper maximum width W1a.

In FIG. 8, (B) is a diagram showing the distribution of the amount of positive fixed charges in the depth direction when the first regions 31 are depleted. The distribution of the amount of positive fixed charges can be obtained, for example, by subtracting the acceptor impurity concentration distribution from the donor impurity concentration distribution. The concentration of the n-type impurity contained in the lower first regions 31b is made lower than the concentration of the n-type impurity contained in the upper first regions 31a. Therefore, as shown in (B) of FIG. 8, when the first regions 31 are depleted, the density of positive fixed charges is lower in the lower first regions 31b than in the upper first regions 31a. Furthermore, between the lower first regions 31b and the upper first regions 31a, there exists a boundary BL2 where the amount of positive fixed charges changes abruptly.

### [Effects]

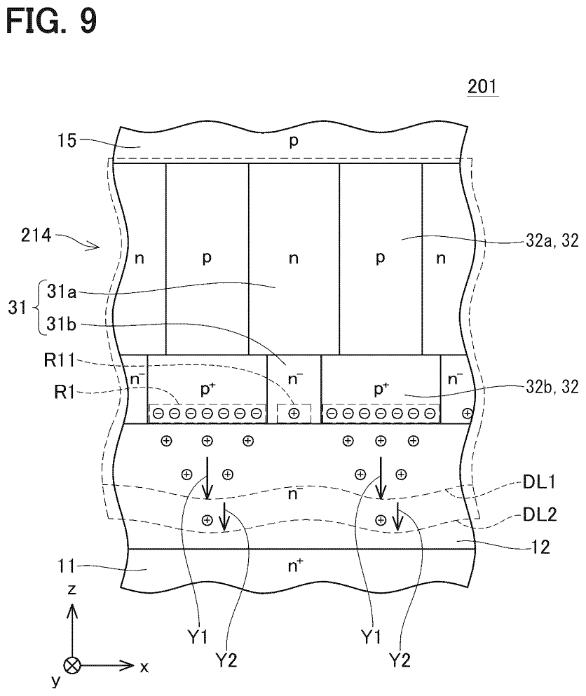

The effects of the second embodiment will be explained with reference to FIG. 9. FIG. 9 is a drawing similar to (A) of FIG. 4 of the first embodiment. As described above, the density of the positive fixed charges during depletion is lower in the lower first regions 31b than in the upper first regions 31a. As a result, the amount of positive fixed charges in the vicinity of the interface IF can be reduced compared to the first embodiment (see region R11 in FIG. 9). In the vicinity of the interface IF, to the extent that the amount of positive fixed charges in the lower first region 31b (region R11) can be reduced, the effect of expanding the depletion layer in the drift region 12 due to the negative fixed charges in the lower second region 32b (region R1) can be enhanced. In other words, the amount of positive fixed charges that balances the amount of negative fixed charges in the lower second regions 32b can be increased in the drift region 12 as a result of the reduction in the lower first regions 31b. As a result, the expansion of the depletion layer in the drift region 12, which is in contact with the lower second regions 32b, can be further promoted from the depletion layer DL1 to a depletion layer DL2 (see arrow Y2).

### [Manufacturing Method of SJ Layer 214]

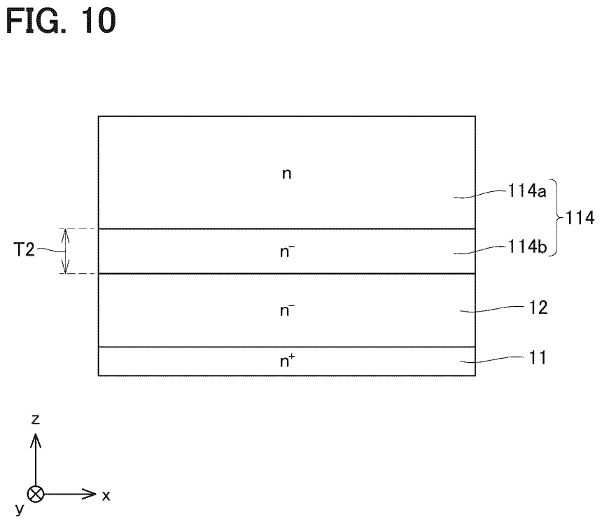

A manufacturing method of the SJ layer 214 of the second embodiment will be described. Only the points different from the manufacturing method of the first embodiment will be described. Using epitaxial growth techniques, the drift region 12 of n-type and the epitaxial layer 114, which are made of silicon carbide, are grown from the surface of the drain region 11. At this time, as shown in FIG. 10, the epitaxial layer 114 is formed to have a lower epitaxial layer 114b with a relatively low concentration of the n-type impurity, and an upper epitaxial layer 114a with a relatively high concentration of the n-type impurity. The thickness T2 of the lower epitaxial layer 114b is set to be the same as the thickness of the lower first regions 31b.

Thereafter, as described in FIG. 6, p-type impurity ions are implanted in multiple stages through the mask 42. As a result, as shown in (A) of FIG. 8, the SJ layer 214 of the second embodiment is completed.

### Third Embodiment

### [Structure of Semiconductor Device 301]

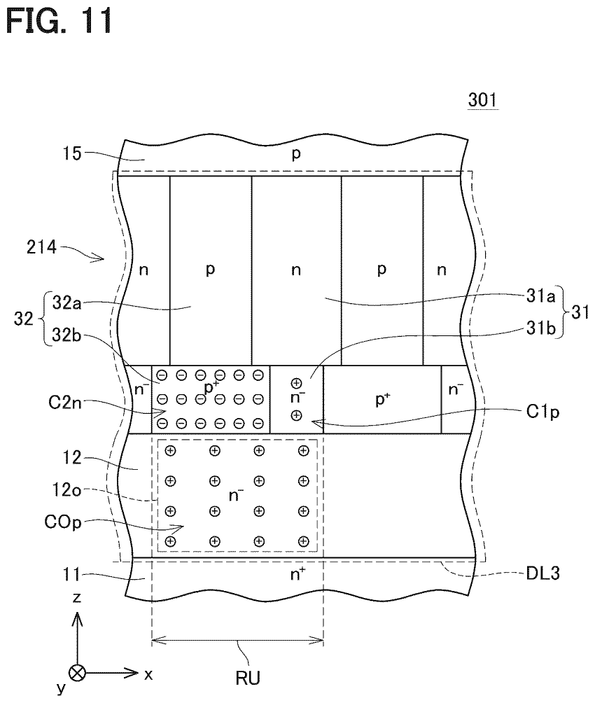

FIG. 11 shows a semiconductor device 301 of a third embodiment. FIG. 11 is a drawing at a position similar to that of FIG. 9 of the second embodiment. For portions common to the second and third embodiments, the same reference numerals are used, and the description thereof is omitted.

The SJ layer 214 has repeating units RU in the x-direction. The repeating unit RU is a unit defined by a pair consisting of the lower first region 31b and the lower second region 32b. Furthermore, the drift region 12 has overlapping regions 12o included in the respective repeating units RU. The overlapping regions 12o are regions that overlap with the repeating units RU when the SJ layer 214 is viewed vertically from above (in the +z-direction).

Here, the total amount of positive fixed charges in the overlapping regions 12o during depletion is defined as an overlapping region total charge COp. The total amount of positive fixed charges in the lower first regions 31b during depletion is defined as a first region total charge C1p. The total amount of negative fixed charges in the lower second regions 32b during depletion is defined as a second region total charge C2n. Accordingly, the semiconductor device 301 of the third embodiment satisfies that relationship that “the second region total charge C2n is equal to or greater than the sum of the first region total charge C1p and the overlapping region total charge COp.”

### [Effects]

When a depletion layer is formed, electrons and holes recombine in a one-to-one ratio, so the number of fixed charges within the depletion layer becomes equal on both the positive and negative sides. Therefore, in the technique of the third embodiment, the relationship “C2n≥C1p+COp” is established. In other words, the amount of negative fixed charges in the lower second regions 32b is set to be sufficient to recombine with the amount of positive fixed charges in the lower first regions 31b and the overlapping regions 12o. As a result, the depletion layer DL3 can be extended to the interface between the drift region 12 and the drain region 11 (see FIG. 11). Since the drift region 12 can be fully depleted, it is possible to maximize the breakdown voltage of the drift region 12.

Although specific examples of the present disclosure have been described in detail above, these are merely examples and do not limit the scope of claims. The techniques described in the claims include various variations and modifications of the specific examples illustrated above. In addition, the technical elements described in the present specification and the drawings exhibit technical usefulness alone or in various combinations, and are not limited to the combinations described in the claims at the time of filing. In addition, the techniques illustrated in the present specification and the drawings can achieve multiple purposes at the same time, and achieving one of the purposes has technical usefulness.

### Modifications

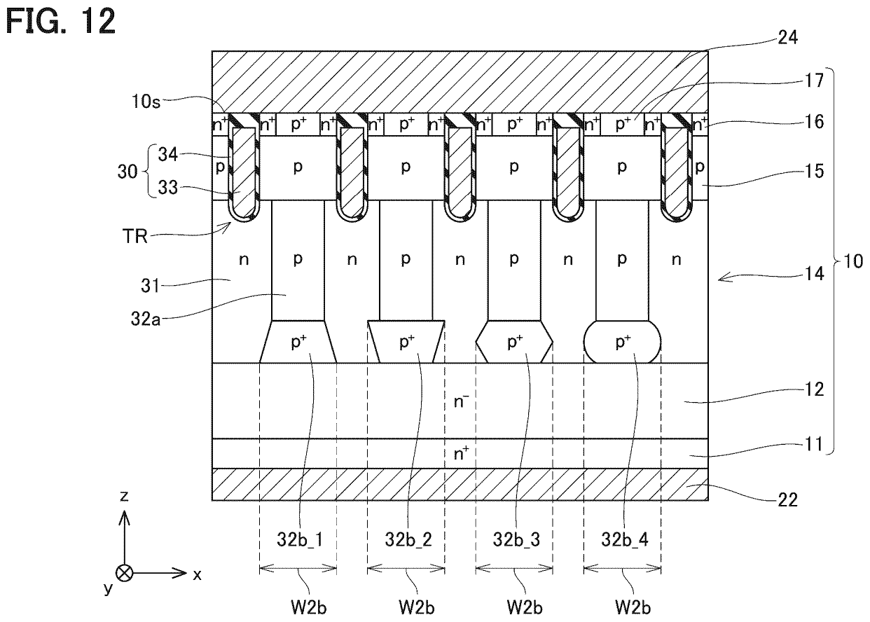

The lower second regions 32b may have various cross-sectional shapes as long as the lower second regions 32b have a lower maximum width W2b greater than the upper maximum width W2a. FIG. 12 shows examples of various cross-sectional shapes of the lower second regions 32b. As shown in a lower second region 32b_1, it is also acceptable to have a cross-sectional shape in which the width in the x-direction increases with depth, reaching a lower maximum width W2b at a lower surface. As shown in a lower second region 32b_2, it is also acceptable to have a cross-sectional shape in which the width in the x-direction increases toward an upper surface, reaching a lower maximum width W2b at the upper surface. As shown in a lower second region 32b_3, it is also acceptable for the width in the x-direction to increase linearly from an upper surface toward an intermediate point, reaching a lower maximum width W2b at the intermediate point, and then decrease linearly in the x-direction from the intermediate point toward a lower surface. Furthermore, as shown in a lower second region 32b_4, it is also acceptable for the width in the x-direction to increase curvilinearly from an upper surface toward an intermediate point, reaching a lower maximum width W2b at the intermediate point, and then decrease curvilinearly in the x-direction from the intermediate point toward a lower surface.

The SJ layer 14 described in the present specification can be applied not only to MOSFETs but also to various device structures such as diodes. Furthermore, the SJ layer 14 described in the present specification is not limited to trench gate structures and can be applied to various gate structures such as planar gate structures.

In the manufacturing method of the SJ layer 14 described in the present specification, the order of the donor impurity and acceptor impurity implantation processes may be reversed. That is, it is also acceptable to implant n-type impurity ions into the epitaxial layer 114 of p-type through a mask.

In the present specification, the case where the first conductivity type is n-type and the second conductivity type is p-type has been described, but the reverse configuration may also be adopted. That is, in the semiconductor device 1 shown in FIG. 1, a structure in which the n-type and the p-type are interchanged may also be adopted.

The SJ structure described in the present specification is not limited to the stripe shape, and various shapes may be adopted. For example, a plurality of n-type columns and a plurality of p-type columns may be arranged in a lattice pattern when viewed in plan from above the semiconductor substrate 10.

The material of the semiconductor substrate 10 is not limited to silicon carbide, and various materials may be adopted. For example, silicon or various wide bandgap semiconductors, such as gallium nitride, gallium oxide, and the like, may also be adopted.

What is claimed is:

1. A semiconductor device comprising:
a voltage sustaining layer of a first conductivity type; and
a superjunction layer disposed in contact with an upper surface of the voltage sustaining layer, and including first regions of the first conductivity type and second regions of a second conductivity type alternately arranged along a first direction,
wherein
each of the second regions includes a lower second region in contact with the voltage sustaining layer and an upper second region disposed in contact with an upper surface of the lower second region,
the lower second region has a lower maximum width that is a maximum width in the first direction of the lower second region,
the upper second region has an upper maximum width that is a maximum width in the first direction of the upper second region,
the lower maximum width is greater than the upper maximum width, and
a density of fixed charges during depletion is higher in the lower second region than in the upper second region.

2. The semiconductor device according to claim 1, wherein
the lower second region has a higher concentration of a second conductivity type impurity than the upper second region.

3. The semiconductor device according to claim 1, wherein
a width in the first direction of the lower second region at an interface between the lower second region and the voltage sustaining layer is the lower maximum width.

4. The semiconductor device according to claim 1, wherein
each of the first regions includes a lower first region in contact with the voltage sustaining layer and an upper first region disposed in contact with an upper surface of the lower first region,
the lower first region is disposed between the lower second regions that are adjacent to each other in the first direction,
the upper first region is disposed between the upper second regions that are adjacent to each other in the first direction, and
the density of fixed charges during depletion is lower in the lower first region than in the upper first region.

5. The semiconductor device according to claim 4, wherein
when viewed vertically from above the superjunction layer, the voltage sustaining layer has overlapping regions that overlap with the lower first regions and the lower second regions,
a total amount of fixed charges in the overlapping regions during depletion is defined as an overlapping region total charge,
a total amount of fixed charges in the lower first regions during depletion is defined as a first region total charge,
a total amount of fixed charges in the lower second regions during depletion is defined as a second region total charge, and
the second region total charge is equal to or greater than a sum of the first region total charge and the overlapping region total charge.

6. The semiconductor device according to claim 1, wherein
the first conductivity type is n-type and the second conductivity type is p-type.

7. A semiconductor device comprising:
a voltage sustaining layer of a first conductivity type; and
a superjunction layer disposed in contact with an upper surface of the voltage sustaining layer, and including first regions of the first conductivity type and second regions of a second conductivity type alternately arranged along a first direction,
wherein
each of the second regions includes a lower second region in contact with the voltage sustaining layer and an upper second region disposed in contact with an upper surface of the lower second region,
the lower second region has a lower maximum width that is a maximum width in the first direction of the lower second region,
the upper second region has an upper maximum width that is a maximum width in the first direction of the upper second region,
the lower maximum width is greater than the upper maximum width, and
the lower second region has a higher concentration of a second conductivity type impurity than the upper second region.
